(19) United States
(12) Patent Application Publication
(10) Pub. No.: US 2021/0382655 A1
(43) Pub. Date: Dec. 9, 2021

(54) MEMORY DEVICE, MEMORY SYSTEM, AND OPERATION METHOD OF MEMORY DEVICE

(71) Applicant: SK hynix Inc., Icheon-si (KR)

(72) Inventor: Ji Seon Yang, Icheon-si (KR)

(21) Appl. No.: 17/087,293

(22) Filed: Nov. 2, 2020

(30) Foreign Application Priority Data
Jun. 9, 2020 (KR) 10-2020-0069520

(51) Int. Cl. G06F 3/06

(52) U.S. Cl. CPC G06F 3/0659; G06F 3/0604; G06F 3/0679

(57) ABSTRACT

Embodiments of the disclosed technology relate to a memory device, a memory system, and an operation method of the memory device. Based on embodiments of the disclosed technology, the memory device may include a reception circuit configured to receive a target command, wherein the target command is a command that is intended for a memory device to execute, from a memory controller; a determination circuit configured to determine whether or not the target command is inexecutable by the memory device; and a response circuit configured to transmit a response message in response to a status-read command received from the memory controller to inform the memory controller regarding whether or not the target command is inexecutable. Accordingly, it is possible to identify information indicating that an inexecutable command is input to the memory device and to eliminate defects caused by an inexecutable command input to the memory device.

### CROSS REFERENCE TO RELATED APPLICATION

This patent document claims the priority and benefits of Korean patent application number 10-2020-0069520 filed on Jun. 9, 2020, which is incorporated herein by reference in its entirety.

### TECHNICAL FIELD

Embodiments of the disclosed technology relate to a memory device, a memory system, and an operation method of a memory device.

### BACKGROUND

A memory system can include a storage device to store data. Such a memory system can operate on the basis of a request from a host, such as computers, mobile devices (e.g., smartphone or tablet PC), or other similar electronic devices. The examples of the memory system span from a traditional hard disk drive (HDD) to a semiconductor-based data storage device such as a solid state drive (SSD), a universal flash storage device (UFS), or an embedded MMC (eMMC) device.

The memory system may further include a memory controller for controlling the memory device. The memory controller may receive a command from the host and execute the command or control read/write/erase operations on the memory devices included in the memory system. The memory controller may also be used to run firmware for performing a logical operation for controlling such operations.

### SUMMARY

The technology disclosed in this patent document can be implemented in various embodiments to provide a memory device, a memory system, and a method for operating a memory device to identify that an inexecutable command has been issued for the memory device.

In addition, some embodiments of the disclosed technology may provide a memory device, a memory system, and a method for operating a memory device reduce/minimize the occurrence of inexecutable command related errors.

In one aspect, embodiments of the disclosed technology may provide a memory device including: a reception circuit configured to receive a target command from a memory controller that is outside the memory device and is operable to control the memory device, wherein the target command is a command that is intended for a memory device to execute; a determination circuit in communication with the reception circuit and configured to determine whether or not the target command is inexecutable by the memory device; and a response circuit in communication with the determination circuit to receive information from the determination circuit on whether or not the target command is inexecutable and configured to transmit a response message in response to a status-read command received from the memory controller to inform the memory controller regarding whether or not the target command is inexecutable.

The determination circuit may be configured to use a ready-busy state of the memory device to determine whether or not the target command is inexecutable, and the ready-busy state of the memory device may be determined to be i) a ready state, ii) a first busy state, or iii) a second busy state, based on an internal busy-state value and an external busy-state value determined based on an operation performed by the memory device.

For example, the response message may include a ready-busy field indicating the ready-busy state of the memory device and indicate whether or not the target command is inexecutable through the ready-busy field.

Upon determination that the target command is inexecutable, the response circuit may be configured to i) reset a first sub-field of the ready-busy field indicating the internal busy-state value of the memory device and ii) set a second sub-field of the ready-busy field indicating the external busy-state value of the memory device.

Thereafter, the response circuit may be configured to transmit another response message in response to a subsequent status-read command received from the memory controller. On the other hand, the response circuit may be configured to, upon receipt of an error clear command from the memory controller, transmit another response message in response to a subsequent status-read command received from the memory controller. The error clear command may be configured to make a request to the memory device for responding to the memory controller with the ready-busy state of the memory device through a response message to a status-read command.

As another example, the response message may include i) a field or a value indicating whether or not the target command is inexecutable and the field or the value may be set differently depending on a command code of the status-read command.

The response circuit may be configured to transmit information on the target command to the memory controller in response to an information request command requesting information on the target command from the memory controller. The information on the target command may include a command code of the target command and address information corresponding to the target command.

In another aspect, embodiments of the disclosed technology may provide an operation method of the memory device.

The operation method of the memory device may include receiving a target command from a memory controller.

The operation method of the memory device may include determining whether or not the target command is inexecutable.

The determining whether or not the target command is inexecutable may be based on a ready-busy state of the memory device. In this case, the ready-busy state of the memory device may be determined to be a ready state, a first busy state, or a second busy state, based on an internal busy-state value and an external busy-state value determined based on an operation performed by the memory device.

The operation method of the memory device may include transmit a response message in response to a status-read command received from the memory controller to inform the memory controller regarding whether or not the target command is inexecutable.

For example, the response message may include a ready-busy field indicating the ready-busy state of the memory device and indicates whether or not the target command is inexecutable through the ready-busy field. Upon determination that the target command is inexecutable, i) a first sub-field of the ready-busy field indicating the internal busy-state value of the memory device may be reset and ii) a second sub-field of the ready-busy field indicating the external busy-state value of the memory device may be set.

The operation method of the memory device may further include transmitting another response message in response to a subsequent status-read command received from the memory controller.

The operation method of the memory device may further include, upon receipt of an error clear command from the memory controller, transmitting another response message in response to a subsequent status-read command received from the memory controller. In this case, the error clear command may be configured to make a request to the memory device for indicating the ready-busy state of the memory device to the memory controller through a response message to a status-read command.

As another example, the response message may include i) a field or a value indicating whether or not the target command is inexecutable, and the field or value may be set differently depending on a command code of the status-read command.

The operation method of the memory device may further include transmitting information on the target command to the memory controller in response to an information request command requesting information on the target command. In this case, the information on the target command may include a command code of the target command and address information corresponding to the target command.

In another aspect, embodiments of the disclosed technology may provide a memory system including a memory device including memory cells for storing data and a memory controller configured to provide a target command to control the memory device.

The memory device may receive the target command from the memory controller.

The memory device may determine whether or not the target command is inexecutable.

The memory device may transmit a response message in response to a status-read command received from the memory controller to inform the memory controller regarding whether or not the target command is inexecutable.

Whether or not the target command is inexecutable may be determined using a ready-busy state of the memory device.

In another aspect, embodiments of the disclosed technology may provide a memory device including: a reception circuit configured to receive a target command from a memory controller; a determination circuit configured to determine whether or not the target command is inexecutable; and a response circuit configured to respond to the memory controller regarding whether or not the target command is inexecutable through a response message to a status-read command received from the memory controller.

The determination circuit may be configured to determine whether or not the target command is inexecutable depending on a ready-busy state of the memory device, and the ready-busy state of the memory device may be determined to be i) a ready state, ii) a first busy state, or iii) a second busy state, based on an internal busy-state value and an external busy-state value determined depending on an operation performed by the memory device.

For example, the response circuit may be configured to respond to the memory controller regarding whether or not the target command is inexecutable through a ready-busy field indicating the ready-busy state of the memory device, among fields in the response message.

The response circuit may be configured to i) reset a first sub-field indicating the internal busy-state value of the memory device and ii) set a second sub-field indicating the external busy-state value of the memory device, among sub-fields included in the ready-busy field, if the target command is inexecutable.

Thereafter, the response circuit may be configured to respond to the memory controller with the ready-busy state of the memory device through a response message to a subsequent status-read command received from the memory controller after transmitting the response message to the memory controller. On the other hand, the response circuit may be configured to respond to the memory controller with the ready-busy state of the memory device through a response message to a subsequent status-read command received from the memory controller after receiving an error clear command from the memory controller. The error clear command may be a command making a request to the memory device for responding to the memory controller with the ready-busy state of the memory device through a response message to a status-read command.

As another example, the response circuit may be configured to determine i) a field indicating whether or not the target command is inexecutable or ii) a value indicating whether or not the target command is inexecutable to be different, among fields of the response message, depending on a command code of the status-read command.

The response circuit may be configured to transmit information on the target command to the memory controller when the reception circuit receives an information request command requesting information on the target command from the memory controller. The information on the target command may include a command code of the target command and address information corresponding to the target command.

In another aspect, embodiments of the disclosed technology may provide an operation method of the memory device.

The operation method of the memory device may include receiving a target command from a memory controller.

The operation method of the memory device may include determining whether or not the target command is inexecutable.

The determining whether or not the target command is inexecutable may include determining whether or not the target command is inexecutable depending on a ready-busy state of the memory device. In this case, the ready-busy state of the memory device may be determined to be a ready state, a first busy state, or a second busy state, based on an internal busy-state value and an external busy-state value determined depending on an operation performed by the memory device.

The operation method of the memory device may include responding to the memory controller regarding whether or not the target command is inexecutable through a response message to a status-read command received from the memory controller.

For example, the responding to the memory controller regarding whether or not the target command is inexecutable may include responding to the memory controller regarding whether or not the target command is inexecutable through a ready-busy field indicating the ready-busy state of the memory device, among fields of the response message. If the target command is inexecutable, among sub-fields included in the ready-busy field, i) a first sub-field indicating the internal busy-state value of the memory device may be reset and ii) a second sub-field indicating the external busy-state value of the memory device may be set.

The operation method of the memory device may further include responding to the memory controller with the ready-busy state of the memory device through a response message to a subsequent status-read command received from the memory controller after transmitting the response message to the memory controller.

The operation method of the memory device may further include responding to the memory controller with the ready-busy state of the memory device through a response message to a subsequent status-read command received from the memory controller after receiving an error clear command from the memory controller. In this case, the error clear command may be a command making a request to the memory device for indicating the ready-busy state of the memory device to the memory controller through a response message to a status-read command.

As another example, the responding to the memory controller regarding whether or not the target command is inexecutable may include determining i) a field indicating whether or not the target command is inexecutable or ii) a value indicating whether or not the target command is inexecutable to be different, among fields of the response message, depending on a command code of the status-read command.

The operation method of the memory device may further include transmitting information on the target command to the memory controller when an information request command requesting information on the target command is received from the memory controller. In this case, the information on the target command may include a command code of the target command and address information corresponding to the target command.

In another aspect, embodiments of the disclosed technology may provide a memory system including a memory device and a memory controller configured to control the memory device.

The memory device may receive a target command from a memory controller.

The memory device may determine whether or not the target command is inexecutable.

The memory device may respond to the memory controller regarding whether or not the target command is inexecutable through a response message to a status-read command received from the memory controller.

In some embodiments of the disclosed technology, it is possible to identify that an inexecutable command has been issued for the memory device, thereby reducing/minimizing the occurrence of inexecutable command related errors.

### BRIEF DESCRIPTION OF THE DRAWINGS

FIG. 1 is a diagram illustrating a schematic configuration of a memory system based on an embodiment of the disclosed technology.

FIG. 2 is a block diagram schematically illustrating a memory device based on an embodiment of the disclosed technology.

FIG. 3 is a diagram illustrating a structure of word lines and bit lines of a memory device based on an embodiment of the disclosed technology.

FIG. 4 is a diagram illustrating the schematic operation of a memory system based on embodiments of the disclosed technology;

FIG. 5 is a flowchart illustrating the operation of a memory controller and a memory device based on embodiments of the disclosed technology;

FIG. 6 is a diagram illustrating the ready-busy state of a memory device based on embodiments of the disclosed technology;

FIG. 7 is a diagram illustrating an example of a format of a response message to a status-read command based on embodiments of the disclosed technology;

FIG. 8 is a diagram illustrating sub-fields in the response message in FIG. 7;

FIG. 9 is a flowchart illustrating an example of an operation in which a memory controller and a memory device process a subsequent status-read command based on embodiments of the disclosed technology;

FIG. 10 is a flowchart illustrating another example of an operation in which a memory controller and a memory device process a subsequent status-read command based on embodiments of the disclosed technology;

FIG. 11 is a diagram illustrating another example of a format of a response message to a status-read command based on embodiments of the disclosed technology;

FIG. 12 is a flowchart illustrating an operation in which a memory controller and a memory device process an information request of a target command based on embodiments of the disclosed technology;

FIG. 13 is a diagram illustrating an example of a format of an information message of a target command based on embodiments of the disclosed technology;

FIG. 14 is a flowchart illustrating an operation method of a memory device based on embodiments of the disclosed technology; and

FIG. 15 is a diagram illustrating the configuration of a computing system based on embodiments of the disclosed technology.

### DETAILED DESCRIPTION OF THE EXEMPLARY EMBODIMENTS

Hereinafter, embodiments of the disclosed technology will be described in detail with reference to the accompanying drawings.

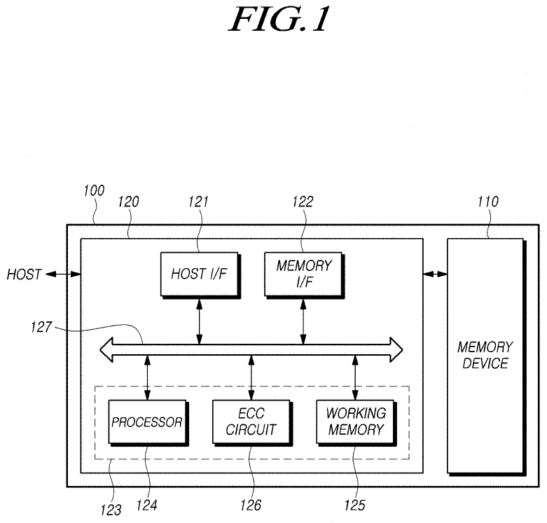

FIG. 1 is a diagram illustrating the schematic configuration of a memory system 100 based on an embodiment of the disclosed technology.

In some implementations, the memory system 100 may include a memory device 110 configured to store data, and a memory controller 120 configured to control the memory device 110.

The memory device 110 may include multiple memory blocks each including a predetermined number of memory cells for storing data. The memory device 110 may be configured to operate in response to control signals received from the memory controller 120. Operations of the memory device 110 may include, for example, a read operation, a program operation (also referred to as a “write operation”), and an erasure operation.

The memory cells in the memory device 110 are used to store data and may be arranged in a memory cell array. In some implementations where the memory device 110 is a flash memory device, the memory cell array may be divided into memory blocks of memory cells and each block includes different pages of memory cells. In some implementations of NAND flash memory devices, a page of cells is the smallest memory unit that can be programmed (or written) and read, and the data stored in memory cells can be erased at the block level.

In some implementations, the memory device 110 may be implemented as various types, such as a double data rate synchronous dynamic random access memory (DDR SDRAM), a low power double data rate fourth generation (LPDDR4) SDRAM, a graphics double data rate (GDDR) SDRAM, a low power DDR (LPDDR), a rambus dynamic random access memory (RDRAM), a NAND flash memory, a vertical NAND flash memory, a NOR flash memory, a resistive random access memory (RRAM), a phase-change memory (PRAM), a magnetoresistive random access memory (MRAM), a ferroelectric random access memory (FRAM), or a spin transfer torque random access memory (STT-RAM).

The memory device 110 may be implemented in a three-dimensional array structure. Some embodiments of the disclosed technology are applicable to any type of flash memory devices having an electric charge storage layer. In an implementation, the electric charge storage layer may be formed of a conductive material, and such an electric charge storage layer can be called a floating gate. In another implementations, the electric charge storage layer may be formed of an insulating material, and such a flash memory device can be called a charge trap flash (CTF).

The memory device 110 may be configured to receive a command and an address from the memory controller 120 to access an area of the memory cell array selected using the address. That is, the memory device 110 may perform an operation corresponding to the received command on a memory area in the memory device having a physical address corresponding to the received address from the controller.

In some implementations, the memory device 110 may perform, among others, a program operation, a read operation, and an erasure operation. During the program operation, the memory device 110 may write (“program”) data to the area selected by the address. During the read operation, the memory device 110 may read data from a memory area selected by the address. During the erasure operation, the memory device 110 may erase data stored in a memory area selected by the address.

The memory controller 120 may control write (program), read, erasure, and background operations to be performed on the memory device 110. The background operation may include operations that are implemented to optimize the overall performance of the memory device 110, such as a garbage collection operation (GC), a wear leveling (WL) operation, and a bad block management (BBM) operation.

The memory controller 120 may control the operation of the memory device 110 at the request of a host. Alternatively, the memory controller 120 may control the operation of the memory device 110 even in absence of request from the host when it performs such a background operation of the memory device.

The memory controller 120 and the host may be separate devices. In some implementations, the memory controller 120 and the host may be integrated in a single device. In the following description, as an example, the memory controller 120 and the host are separate devices.

Referring to FIG. 1, the memory controller 120 may include a memory interface 122, a control circuit 123, and a host interface 121.

The host interface 121 may be configured to provide an interface for communication with the host.

When receiving a command from the host HOST, the control circuit 123 may receive the command through the host interface 121 and may perform an operation of processing the received command.

The memory interface 122 may be directly or indirectly connected to the memory device 110 to provide an interface for communication with the memory device 110. That is, the memory interface 122 may be configured to provide the memory device 110 and the memory controller 120 with an interface for the memory controller 120 to perform memory operations on the memory device 110 based on control signals and instructions from the control circuit 123.

The control circuit 123 may be configured to control the operation of the memory device 110 through the memory controller 120. For example, the control circuit 123 may include a processor 124 and a working memory 125. The control circuit 123 may further include an error detection/correction circuit (ECC circuit) 126.

The processor 124 may control the overall operation of the memory controller 120. The processor 124 may perform a logical operation. The processor 124 may communicate with the host HOST through the host interface 121. The processor 124 may communicate with the memory device 110 through the memory interface 122.

The processor 124 may be used to run a flash translation layer (FTL) to effectively manage the memory operations on the memory system 100. For example, the processor 124 may translate a logical block address (LBA) provided by the host into a physical block address (PBA) through the FTL. The FTL may receive the LBA and translate the LBA into the PBA by using a mapping table.

There are various address mapping methods which may be employed by the FTL, based on the mapping unit. Typical address mapping methods may include a page mapping method, a block mapping method, and a hybrid mapping method.

The processor 124 may be configured to randomize data received from the host to write the randomized data to the memory cell array. For example, the processor 124 may randomize data received from the host by using a randomizing seed. The randomized data is provided to the memory device 110 and written to the memory cell array.

The processor 124 may be configured to derandomize data received from the memory device 110 during a read operation.

For example, the processor 124 may derandomize data received from the memory device 110 by using a derandomizing seed. The derandomized data may be output to the host HOST.

The processor 124 may execute firmware (FW) to control the operation of the memory controller 120. In other words, the processor 124 may control the overall operation of the memory controller 120 and, in order to perform a logical operation, may execute (drive) firmware loaded into the working memory 125 during booting.

The firmware refers to a program or software stored on a certain nonvolatile memory and is executed inside the memory system 100.

In some implementations, the firmware may include various functional layers. For example, the firmware may include at least one of a flash translation layer (FTL) configured to translate a logical address in the host HOST requests to a physical address of the memory device 110, a host interface layer (HIL) configured to interpret a command that the host HOST issues to a data storage device such as the memory system 100 and to deliver the command to the FTL, and a flash interface layer (FIL) configured to deliver a command issued by the FTL to the memory device 110.

For example, the firmware may be stored in the memory device 110, and then loaded into the working memory 125.

The working memory 125 may store firmware, program codes, commands, or pieces of data necessary to operate the memory controller 120. The working memory 125 may include, for example, at least one among a static RAM (SRAM), a dynamic RAM (DRAM), and a synchronous RAM (SDRAM) as a volatile memory.

The error detection/correction circuit 126 may be configured to detect and correct one or more erroneous bits in the data by using an error detection and correction code. In some implementations, the data that is subject to the error detection and correction may include data stored in the working memory 125, and data retrieved from the memory device 110.

The error detection/correction circuit 126 may be implemented to decode data by using the error correction code. The error detection/correction circuit 126 may be implemented by using various decoding schemes. For example, a decoder that performs nonsystematic code decoding or a decoder that performs systematic code decoding may be used.

In some implementations, the error detection/correction circuit 126 may detect one or more erroneous bits on a sector basis. That is, each piece of read data may include multiple sectors. In the context of this patent document, a “sector” may refer to a data unit that is smaller than the smallest unit for read operations (e.g., page) of a flash memory. Sectors constituting each piece of read data may be mapped based addresses.

In some implementations, the error detection/correction circuit 126 may calculate a bit error rate (BER) and determine whether the number of erroneous bits in the data is within the error correction capability sector by sector. For example, if the BER is higher than a reference value, the error detection/correction circuit 126 may determine that the erroneous bits in the corresponding sector are uncorrectable and the corresponding sector is marked “fail.” If the BER is lower than the reference value, the error detection/correction circuit 126 may determine that the corresponding sector is correctable and the corresponding sector can be marked “pass.”

The error detection/correction circuit 126 may perform error detection and correction operations successively on all read data. When a sector included in the read data is correctable, the error detection/correction circuit 126 may go on to the next sector to check as to whether an error correction operation is needed on the next sector. Upon completion of the error detection and correction operations on all the read data in this manner, the error detection/correction circuit 126 may identify which sector is deemed uncorrectable in the read data. The error detection/correction circuit 126 may provide information (e.g., address of uncorrectable sector) regarding the sectors deemed uncorrectable to the processor 124.

The memory system 100 may also include a bus 127 to provide a channel between the constituent elements 121, 122, 124, 125, and 126 of the memory controller 120. The bus 127 may include, for example, a control bus for delivering various types of control signals and commands, and a data bus for delivering various types of data.

The above-mentioned constituent elements 121, 122, 124, 125, and 126 of the memory controller 120 are illustrated in FIG. 1 by way of example. It is noted that some of the above-mentioned constituent elements 121, 122, 124, 125, and 126 of the memory controller 120 may be omitted, or some of the above-mentioned constituent elements 121, 122, 124, 125, and 126 of the memory controller 120 may be integrated into a single element. In addition, in some implementations, one or more other constituent elements may be added to the above-mentioned constituent elements of the memory controller 120.

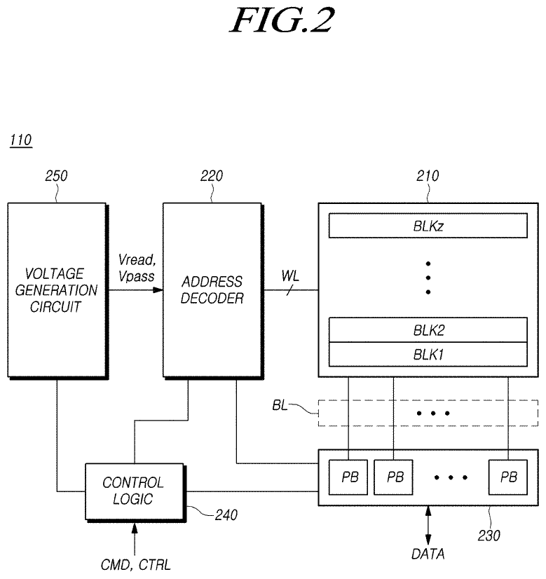

Hereinafter, the memory device 110 will be described in more detail with reference to FIG. 2.

FIG. 2 is a block diagram schematically illustrating a memory device 110 based on an embodiment of the disclosed technology.

In some implementations, the memory device 110 based on an embodiment of the disclosed technology may include a memory cell array 210, an address decoder 220, a read/write circuit 230, a control logic 240, and a voltage generation circuit 250.

The memory cell array 210 may include multiple memory blocks BLK1-BLKz, where z is a natural number equal to or larger than 2.

In the multiple memory blocks BLK1-BLKz, multiple word lines WL and multiple bit lines BL may be arranged in rows and columns, and multiple memory cells MC may be arranged.

The multiple memory blocks BLK1-BLKz may be connected to the address decoder 220 through the multiple word lines WL. The multiple memory blocks BLK1-BLKz may be connected to the read/write circuit 230 through the multiple bit lines BL.

Each of the multiple memory blocks BLK1-BLKz may include multiple memory cells. For example, the multiple memory cells are nonvolatile memory cells. In some implementations, such nonvolatile memory cells may be arranged in a vertical channel structure.

The memory cell array 210 may be configured as a memory cell array having a two-dimensional structure and, in some implementations, may be arranged in a three-dimensional structure.

Each of the multiple memory cells included in the memory cell array 210 may store at least one bit of data. For example, each of the multiple memory cells included in the memory cell array 210 may be a single-level cell (SLC) configured to store one bit of data per memory cell. As another example, each of the multiple memory cells included in the memory cell array 210 may be a multi-level cell (MLC) configured to store two bits of data per memory cell. As another example, each of the multiple memory cells included in the memory cell array 210 may be a triple-level cell (TLC) configured to store three bits of data per memory cell. As another example, each of the multiple memory cells included in the memory cell array 210 may be a quad-level cell (QLC) configured to store four bits of data. As another example, the memory cell array 210 may include multiple memory cells that are configured to store at least five bits of data per memory cell.

Referring to FIG. 2, the address decoder 220, the read/write circuit 230, the control logic 240, and the voltage generation circuit 250 may operate as peripheral circuits configured to drive the memory cell array 210.

The address decoder 220 may be connected to the memory cell array 210 through the multiple word lines WL.

The address decoder 220 may be configured to operate in response to commands and control signals of the control logic 240.

The address decoder 220 may receive addresses through an input/output buffer inside the memory device 110. The address decoder 220 may be configured to decode a block address among the received addresses. The address decoder 220 may select at least one memory block based on the decoded block address.

The address decoder 220 may receive a read voltage Vread and a pass voltage Vpass from the voltage generation circuit 250.

The address decoder 250 may apply the read voltage Vread to a selected word line WL inside a selected memory block, when applying the read voltage during a read operation, and may apply the pass voltage Vpass to the remaining non-selected word lines WL.

The address decoder 220 may apply a verification voltage generated by the voltage generation circuit 250 to a selected word line WL inside a selected memory block, during a program verification operation, and may apply the pass voltage Vpass to the remaining non-selected word lines WL.

The address decoder 220 may be configured to decode a column address among the received addresses. The address decoder 220 may transmit the decoded column address to the read/write circuit 230.

The memory device 110 may perform the read operation and the program operation on a page by page basis. Addresses received when the read operation and the program operation are requested may include at least one of a block address, a row address, and a column address.

The address decoder 220 may select one memory block and one word line based on the block address and the row address. The column address may be decoded by the address decoder 220 and provided to the read/write circuit 230.

The address decoder 220 may include at least one of a block decoder, a row decoder, a column decoder, and an address buffer.

The read/write circuit 230 may include multiple page buffers PB. The read/write circuit 230 may operate as a “read circuit” when the memory cell array 210 performs a read operation, and may operate as a “write circuit” when the memory cell array 210 performs a write operation.

The above-mentioned read/write circuit 230 is also referred to as a page buffer circuit including multiple page buffers PB, or a data register circuit. The read/write circuit 230 may include a data buffer that can hold data for data processing and, in some implementations, may further include a cache buffer for data caching.

The multiple page buffers PB may be connected to the memory cell array 210 through the multiple bit lines BL. In order to detect or sense the threshold voltage Vth of the memory cells during a read operation and a program verification operation, the multiple page buffers PB may continuously supply a sensing current to the bit lines BL connected to the memory cells to detect, at a sensing node, a change in the amount of current that flows based on the program state of a corresponding memory cell, and may hold or latch the corresponding voltage as sensing data.

The read/write circuit 230 may operate in response to page buffer control signals output from the control logic 240.

During a read operation, the read/write circuit 230 senses a voltage value of a memory cell and the voltage value is read out as data. The read/write circuit 230 temporarily stores the retrieved data, and outputs the data DATA to the input/output buffer of the memory device 110. In an embodiment, the read/write circuit 230 may include a column selection circuit, in addition to the page buffers PB or page registers.

The control logic 240 may be connected to the address decoder 220, the read/write circuit 230, and the voltage generation circuit 250. The control logic 240 may receive a command CMD and a control signal CTRL through the input/output buffer of the memory device 110.

The control logic 240 may be configured to control the overall operation of the memory device 110 in response to the control signal CTRL. The control logic 240 may output a control signal for adjusting the voltage level at sensing nodes of multiple page buffers PB.

The control logic 240 may control the read/write circuit 230 to perform a read operation on the memory cells in the memory cell array 210. The voltage generation circuit 250 may generate a read voltage Vread and a pass voltage Vpass, which are used during the read operation, in response to a voltage generation circuit control signal provided by the control logic 240.

A memory block BLK included in the memory device 110 may consist of multiple pages PG, each of which includes a plurality of memory cells. In some implementations, the plurality of memory cells can be arranged in multiple strings. The multiple pages PG can be mapped to multiple word lines WL, and the multiple strings STR can be mapped to multiple bit lines BL.

In the memory block BLK, multiple word lines WL and multiple bit lines BL may be arranged in rows and columns. For example, each of the multiple word lines WL may be arranged in the row direction, and each of the multiple bit lines BL may be arranged in the column direction. As another example, each of the multiple word lines WL may be arranged in the column direction, and each of the multiple bit lines BL may be arranged in the row direction.

The multiple word lines WL and the multiple bit lines BL may intersect with each other when viewed from above, thereby defining a memory array including multiple memory cells MC. Each memory cell MC may have a transistor TR arranged therein.

For example, the transistor TR arranged in each memory cell MC may include a drain, a source, and a gate. The drain (or source) of the transistor TR may be connected to the corresponding bit line BL directly or via another transistor TR. The source (or drain) of the transistor TR may be connected to the source line (which may be the ground) directly or via another transistor TR. The gate of the transistor TR may include a floating gate (FG) surrounded by an insulator, and a control gate (CG) to which a gate voltage is applied from a word line WL.

In each of the multiple memory blocks BLK1-BLKz, a first selection line (also referred to as a source selection line or a drain selection line) may be additionally arranged outside the first outermost word line, which is closer to the read/write circuit 230 among two outermost word lines, and a second selection line (also referred to as a drain selection line or a source selection line) may be additionally arranged outside the other second outermost word line.

In some cases, at least one dummy word line may be additionally arranged between the first outermost word line and the first selection line. In addition, at least one dummy word line may be additionally arranged between the second outermost word line and the second selection line.

A read operation and a program operation (write operation) of the memory block may be performed on a page by page basis, and an erasure operation may be performed on a memory block by memory block basis.

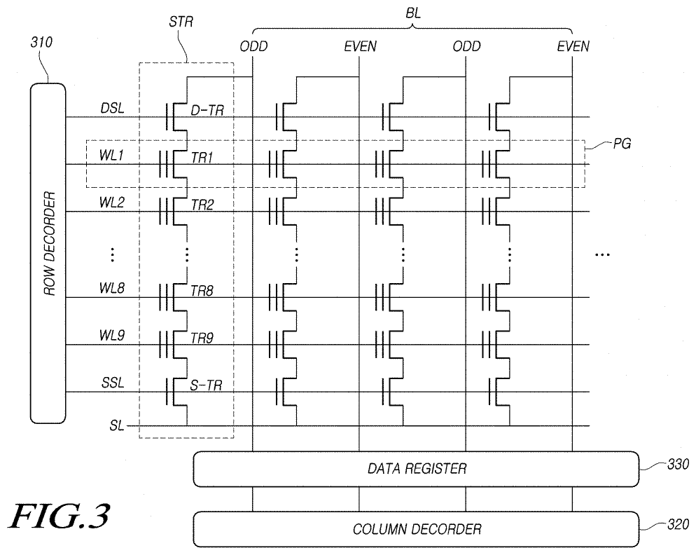

FIG. 3 is a diagram illustrating a structure of word lines WL and bit lines BL of a memory device 110 based on an embodiment of the disclosed technology.

Referring to FIG. 3, the memory device 110 has a core area in which memory cells MC are concentrated, and an auxiliary area which corresponds to the remaining area other than the core area. The auxiliary area includes circuitry for supporting the operations of the memory cell array 210.

The core area may include pages PG and strings STR. In some implementations, multiple word lines WL1-WL9 and multiple bit lines BL are arranged to intersect when viewed from above.

The word lines WL1-WL9 may be connected to a row decoder 310. The bit lines BL may be connected to a column decoder 320. A data register 330, which corresponds to the read/write circuit 230 of FIG. 2, may exist between the multiple bit lines BL and the column decoder 320.

The multiple word lines WL1-WL9 may correspond to multiple pages PG.

For example, each of the multiple word lines WL1-WL9 may correspond to one page PG as illustrated in FIG. 3. When each of the multiple word lines WL1-WL9 has a large size, each of the multiple word lines WL1-WL9 may correspond to at least two (e.g., two or four) pages PG. Each page PG is the smallest unit in connection with conducting a program operation and a read operation, and all memory cells MC within the same page PG may perform simultaneous operations when conducting a program operation and a read operation.

The multiple bit lines BL may be connected to the column decoder 320. In some implementations, the multiple bit lines BL may be divided into odd-numbered bit lines BL and even-numbered bit lines BL such that a pair of odd-numbered bit line BL and even-numbered bit line B are coupled in common to a column decoder 320.

The address may be used to access one or more memory cells MC in the core area. The address can be provided through the input/output end to the row decoder 310 and the column decoder 320 to select a corresponding target memory cell. In the context of this patent document, the word “target memory cell” can be used to indicate one of the memory cells MC targeted to be accessed from the memory controller or the user.

Pages PG in a first direction (for example, X-axis direction) are connected to a commonly used line referred to as a word line WL, and strings STR in a second direction (for example, Y-axis direction) are connected to a common line referred to as a bit line BL. The voltage applied to a memory cell MC in the middle position or last position among memory cells MC connected in series may slightly differ from the voltage applied to the memory cell MC in the first position and from the voltage applied to the memory cell MC in the last position, due to the voltage drop across the preceding memory cell MC.

In some implementations, the data register 330 plays an important role because all data processing by the memory device 110, including program and read operations, occurs via the data register 330. If data processing by the data register 330 is delayed, all of the other areas need to wait until the data register 330 finishes the data processing, degrading the overall performance of the memory device 110.

Referring to the example illustrated in FIG. 3, in one string STR, multiple transistors TR1-TR9 may be connected to multiple word lines WL1-WL9, respectively. In some implementations, the multiple transistors TR1-TR9 correspond to memory cells MC. In this example, the multiple transistors TR1-TR9 include control gates CG and floating gates FG.

The multiple word lines WL1-WL9 include two outermost word lines WL1 and WL9. A first selection line DSL may be additionally arranged outside the first outermost word line WL1, which is closer to the data register 330 and has a shorter signal path compared to the other outermost word line WL9. A second selection line SSL may be additionally arranged outside the other second outermost word line WL9.

The first selection transistor D-TR, which is controlled to turn on/off by the first selection line DSL, has a gate electrode connected to the first selection line DSL, but includes no floating gate FG. The second selection transistor S-TR, which is controlled to turn on/off by the second selection line SSL, has a gate electrode connected to the second selection line SSL, but includes no floating gate FG.

The first selection transistor D-TR is used as a switch circuit that connects the corresponding string STR to the data register 330. The second selection transistor S-TR is used as a switch circuit that connects the corresponding string STR to the source line SL.

That is, the first selection transistor D-TR and the second selection transistor S-TR can be used to enable or disable the corresponding string STR.

During a program operation, the memory system 100 fills the target memory cell MC of the bit line BL which is to be programmed with electrons. Accordingly, the memory system 100 applies a predetermined turn-on voltage Vcc to the gate electrode of the first selection transistor D-TR, thereby turning on the first selection transistor D-TR, and applies a predetermined turn-off voltage (for example, 0V) to the gate electrode of the second selection transistor S-TR, thereby turning off the second selection transistor S-TR.

The memory system 100 turns on both of the first and second selection transistors D-TR and S-TR during a read operation or a verification operation. Accordingly, during a read operation or a verification operation, an electric current may flow through the corresponding string STR and drain to the source line SL, which corresponds to the ground voltage, such that the voltage level of the bit line BL can be measured. However, during a read operation, there may be a time difference in the on/off timing between the first selection transistor D-TR and the second selection transistor S-TR.

The memory system 100 may apply a predetermined voltage (e.g., +20V) to the substrate through a source line SL during an erasure operation. The memory system 100 applies a certain voltage to allow both the first selection transistor D-TR and the second selection transistor S-TR to float during an erasure operation. As a result, the applied erasure voltage can remove electrical charges from the floating gate FG of the selected memory cell.

When the memory controller performs firmware operations, an inexecutable command can be generated due to an error in the firmware, and there is a probability for the memory controller to receive such an inexecutable command. In some cases, the memory device does not respond to inform the memory controller that an inexecutable command has been generated, and thus the memory controller is unable to identify the causes of the malfunction when a memory system malfunctions due to an inexecutable command. The technology disclosed in this patent document can be implemented in various embodiments to identify that an inexecutable command has been issued for the memory device.

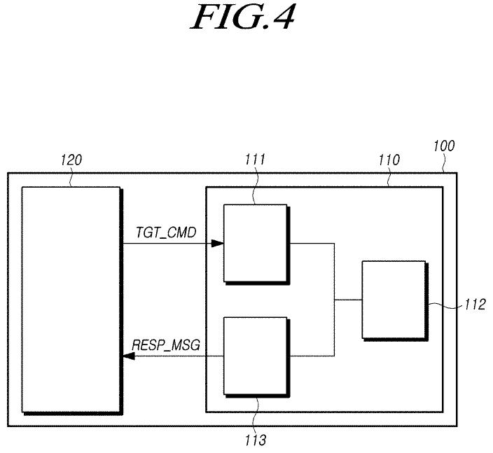

FIG. 4 is a diagram illustrating the schematic operation of a memory system 100 based on embodiments of the disclosed technology.

Referring to FIG. 4, a memory device 110 of the memory system 100 may include a reception circuit 111, a determination circuit 112, and a response circuit 113.

The reception circuit 111 of the memory device 110 may receive a target command TGT_CMD from the memory controller 120.

The target command TGT_CMD is a command by which the memory controller 120 makes a request to the memory device 110 for performing a specific operation. Therefore, such a target command is a command sent by the memory controller and for the memory device 110 to execute. For example, the target command TGT_CMD may be a command requesting execution of an operation of reading data stored in a page PG, a command requesting execution of an operation of erasing a memory block BLK, a command requesting status information on the memory device 110. However, such a target command may not be actually executed by the memory device 110 due to various reasons including, for example, the action to be executed as defined by the target command may be in conflict with another operation already in progress. In this context, the “target command” is a command for a targeted or intended action. Whether or not such a target command can be executed by the memory device 110 depends an evaluation of the condition of the memory device 110 by the determination circuit 112 within the memory device 110.

The determination circuit 112 of the memory device 110 is coupled to both the reception circuit 111 and the response circuit 113 as shown in FIG. 4 and is designed to determine whether or not the target command TGT_CMD received by the reception circuit 111 is inexecutable. In operation, the determination circuit 112 may store information on whether or not the target command TGT_CMD is inexecutable and information on the target command TGT_CMD (e.g., a command code of the target command, an address indicated by the target command) in any one of the memory blocks BLK inside the memory device 110 or in a separate volatile memory (not shown) included in the memory device 110. The volatile memory may be

SRAM, DRAM, or SDRAM, for example.

In the context of this patent document, the word “inexecutable” that is used with respect to the target command TGT_CMD can indicate that the memory device 110 is unable to execute the target command TGT_CMD at the time of determining whether or not the target command TGT_CMD is executable.

For example, while an operation of erasing a memory block BLK is being executed, a target command TGT_CMD, requesting an operation of reading a page included in the corresponding memory block BLK, is an inexecutable command during the execution of reading the page. This is due to the conflicts between operations of the memory device since it is impossible to read a page included in a memory block BLK during the operation of erasing the corresponding memory block BLK.

On the other hand, while an operation of erasing a memory block BLK is being executed, a target command TGT_CMD, requesting an operation of reading a page included in a memory block, other than the corresponding memory block BLK, is an executable command because the read operation and the erase operation are accessing different memory locations, and during the operation of erasing a memory block BLK, reading a page included in another memory block BLK is possible.

Therefore, the determination circuit 112 is structured to process the information in a target command received by the reception 111 and, based on this processing, to make the determination. In addition, the determination circuit 112 generates an indication of this determination of whether the target command is executable and communicates this indication to the response circuit 113.

The response circuit 113 of the memory device 110 may transmit, to the memory controller 120, an indication as to whether the target command TGT_CMD described above is inexecutable through a response message to a status-read command received from the memory controller 120.

The memory controller 120 may transmit, to the memory device 110, a status-read command to indicate the execution status of the target command TGT_CMD and/or the status of the memory device 110. In addition, the memory device 110 may generate a response message RESP_MSG to the status-read command received from the memory controller 120, and may transmit the response message RESP_MSG to the memory controller 120.

Here, the response circuit 113 of the memory device 110 may include, in the response message to the status-read command, the indication as to whether or not the target command TGT_CMD is inexecutable when transmitting the response message to the memory controller 120.

Accordingly, the memory controller 120 may identify whether or not the target command TGT_CMD is inexecutable through the response message to the status-read command, and if the target command TGT_CMD is inexecutable, the memory controller 120 may perform operations that can correct the errors arising from the inexecutable target command.

In some implementations, the reception circuit 111, the determination circuit 112, and the response circuit 113 of the memory device 110 described above may be implemented as a complex programmable logic device (CPLD), a field programmable gate array (FPGA), ROM, a micro-processor for executing specified software, and the like.

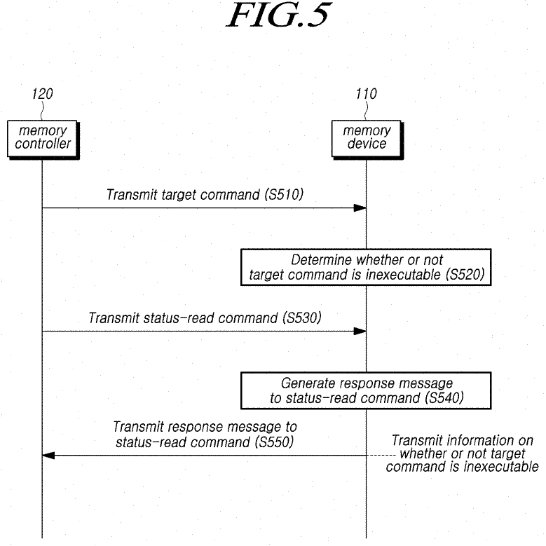

FIG. 5 is a flowchart illustrating the operation of a memory controller 120 and a memory device 110 based on embodiments of the disclosed technology.

In some implementations, the memory controller 120 may transmit a target command TGT_CMD to the memory device 110 (S510).

The memory device 110 determines whether or not the target command TGT_CMD received from the memory controller 120 is inexecutable (S520). As described above in FIG. 4, upon determination that the target command TGT_CMD received from the memory controller 120 is inexecutable, the memory device 110 may store an indication that the target command TGT_CMD received from the memory controller 120 is inexecutable and information on the target command TGT_CMD in at least one of the memory blocks BLK in the memory device 110 or in a separate volatile memory (not shown) included in the memory device 110.

The memory controller 120 may transmit a status-read command to the memory device 110 (S530). The memory device 110 may generate a response message RESP_MSG to the status-read command (S540). In some implementations, the response message RESP_MSG includes an indication as to whether or not the target command TGT_CMD is inexecutable.

The memory device 110 may transmit the generated response message RESP_MSG to the memory controller 120 (S550).

In some implementations, criteria for the determination circuit 112 of the memory device 110 to determine whether or not the target command TGT_CMD is inexecutable may be based on various parameters or indicators associated with the status of the memory device 110.

For example, in embodiments of the disclosed technology, the determination circuit 112 may determine that the target command TGT_CMD is inexecutable based on a ready-busy state RB_STATE of the memory device 110.

In some implementations, the ready-busy state RB_STATE of the memory device 110 may be used to determine that the target command TGT_CMD is inexecutable as will be discussed below.

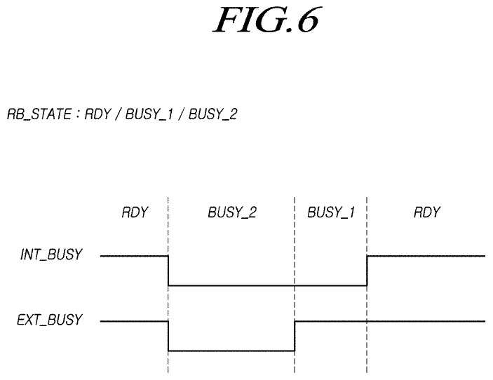

FIG. 6 is a diagram illustrating a ready-busy state RB_STATE of a memory device 110 based on embodiments of the disclosed technology.

In some implementations, the ready-busy state RB_STATE of the memory device 110 may be i) a ready state RDY, ii) a first busy state BUSY_1, or iii) a second busy state BUSY_2.

The ready state RDY indicates the state in which the memory device 110 is ready to execute a command received from the memory controller 120.

The first busy state BUSY_1 indicates that even though the memory device 110 is in a “busy” state (the state in which the operation requested by the received command is being executed), a specific type of command among other commands received from the memory controller 120 is ready for execution.

The second busy state BUSY_2 indicates the state in which the memory device 110 is in a “busy” state and all other commands received from the memory controller 120 are unable to be executed.

In some implementations, the memory device 110 may output a signal indicating whether or not the ready-busy state RB_STATE of the memory device 110 is the second busy state BUSY_2 to the outside of the memory device 110. Accordingly, the memory controller 120 may identify whether or not the ready-busy state RB_STATE of the memory device 110 is the second busy state BUSY_2 through the signal output from the memory device 110. On the other hand, the memory device 110 does not output a signal indicating whether or not the ready-busy state RB_STATE of the memory device 110 is the first busy state BUSY_1 to the outside of the memory device 110.

Referring to FIG. 6, the memory device 110 may use an internal busy-state value INT_BUSY and an external busy-state value EXT_BUSY in order to manage the ready-busy state RB_STATE of the memory device 110. The internal busy-state value INT_BUSY and the external busy-state value EXT_BUSY may be determined to be “low” (e.g., logic low value) or high (e.g., logic high value) depending on the operation performed by the memory device 110.

For example, if both the internal busy-state value INT_BUSY and the external busy-state value EXT_BUSY are “high,” the ready-busy state RB_STATE of the memory device 110 may be a ready state RDY.

If both the internal busy-state value INT_BUSY and the external busy-state value EXT_BUSY are “low,” the ready-busy state RB_STATE of the memory device 110 may be a second busy state BUSY_2.

If the internal busy-state value INT_BUSY is “low,” and if the external busy-state value EXT_BUSY is “high,” the ready-busy state RB_STATE of the memory device 110 may be a first busy state BUSY_1.

However, there is no case in which the internal busy-state value INT_BUSY is “high” and the external busy-state value EXT_BUSY is “low.” If both the internal busy-state value INT_BUSY and the external busy-state value EXT_BUSY switch from “high” to “low,” the external busy-state value EXT_BUSY switches from “low” to “high” before the internal busy-state value INT_BUSY switches from “low” to “high.”

In some implementations, the memory device 110 can determine whether or not the target command TGT_CMD is inexecutable based on the ready-busy state RB_STATE of the memory device 110.

For example, when the ready-busy state RB_STATE is a ready state RDY, the memory device 110 may execute the target command TGT_CMD without limitation.

For example, when the ready-busy state RB_STATE is a first busy state BUSY_1, the memory device 110 may execute a status-read command and a reset command.

When the ready-busy state RB_STATE is the first busy state BUSY_1, the memory device 110 may further execute another target command TGT_CMD depending on the type of operation that is being processed.

If the memory device 110 is executing a sequential cache read command for a specific logical unit LUN, the memory device 110 may execute a random data-out command and a cache exit-input command for the corresponding logical unit LUN, as well as the status-read command and the reset command described above, when the ready-busy state RB_STATE is the first busy state BUSY_1.

If the memory device 110 is executing a random cache read command for a specific logical unit LUN, the memory device 110 may execute a random data-out command and a cache exit-input command for the corresponding logical unit LUN, as well as the status-read command and the reset command described above, when the ready-busy state RB_STATE is the first busy state BUSY_1.

If the memory device 110 is executing a one-shot program command for a specific logical unit LUN, the memory device 110 may execute a cache program command for the corresponding logical unit LUN, as well as the status-read command and the reset command described above, when the ready-busy state RB_STATE is the first busy state BUSY_1.

In some implementations, as will be discussed below, the response circuit 113 of the memory device 110 can respond to the memory controller 120 regarding whether or not the target command TGT_CMD is inexecutable through a response message RESP_MSG to the status-read command.

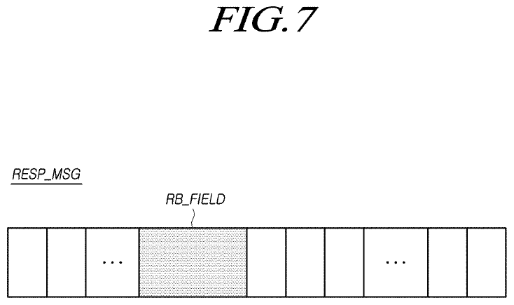

FIG. 7 is a diagram illustrating an example of a format of a response message RESP_MSG to a status-read command based on embodiments of the disclosed technology.

In some implementations, the response message RESP_MSG to a status-read command may include a ready-busy field RB_FIELD indicating the ready-busy state of the memory device 110.

In embodiments of the disclosed technology, the response circuit 113 of the memory device 110 may respond to the memory controller 120 regarding whether or not the target command TGT_CMD is inexecutable through the ready-busy field RB_FIELD described above.

In some implementations, the memory controller 120 may distinguish the ready-busy field RB_FIELD that indicates the ready-busy state RB_STATE of the memory device 110 from the ready-busy field RB_FIELD that indicates the target command TGT_CMD is inexecutable. In this way, the memory controller 120 can avoid misinterpreting information indicated by the ready-busy field RB_FIELD.

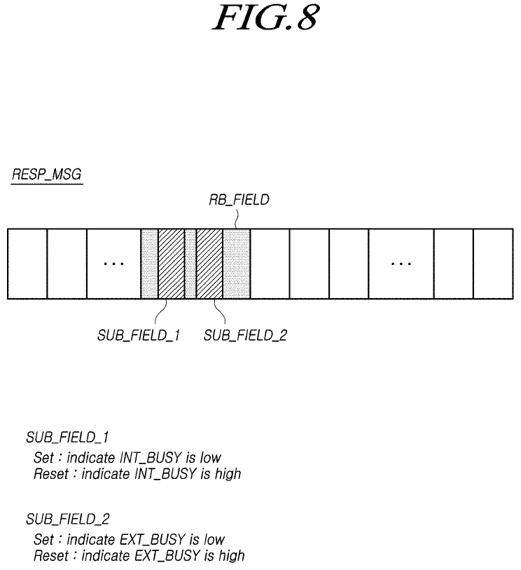

In some implementations, the memory device 110 configures a response message RESP_MSG in a way that prevents the memory controller 120 from misinterpreting information indicated by the ready-busy field RB_FIELD, as will be described with reference to FIG. 8.

FIG. 8 is a diagram illustrating a sub-field of the response message RESP_MSG shown in FIG. 7.

In some implementations, the ready-busy field RB_FIELD may include i) a first sub-field SUB_FIELD_1 indicating an internal busy-state value INT_BUSY of the memory device 110 and ii) a second sub-field SUB_FIELD_2 indicating an external busy-state value EXT_BUSY of the memory device 110.

If the first sub-field SUB_FIELD_1 is set, the first sub-field SUB_FIELD_1 indicates that the internal busy-state value INT_BUSY of the memory device 110 is “low.” On the other hand, if the first sub-field SUB_FIELD_1 is reset, the first sub-field SUB_FIELD_1 indicates that the internal busy-state value INT_BUSY of the memory device 110 is “high.” The value (e.g., 0), indicating the state in which the first sub-field SUB_FIELD_1 is set, may be arbitrarily determined, and is different from the value (e.g., 1) indicating the state in which the first sub-field SUB_FIELD_1 is reset.

Likewise, if the second sub-field SUB_FIELD_2 is set, the second sub-field SUB_FIELD_2 indicates that the external busy-state value EXT_BUSY of the memory device 110 is “low.” On the other hand, if the second sub-field SUB_FIELD_2 is reset, the second sub-field SUB_FIELD_2 indicates that the external busy-state value EXT_BUSY of the memory device 110 is “high.” The value (e.g., 0) indicating the state in which the second sub-field SUB_FIELD_2 is set may be set to be different from the value (e.g., 1) indicating the state in which the second sub-field SUB_FIELD_2 is reset.

In some implementations, the response circuit 113 of the memory device 110 may reset the first sub-field SUB_FIELD_1, and may set the second sub-field SUB_FIELD_2 in order to indicate that the target command TGT_CMD is inexecutable.

As described in FIG. 6 above, there is no case in which the internal busy-state value INT_BUSY of the memory device 110 is high and the external busy-state value EXT_BUSY thereof is low. Accordingly, there is no case in which the first sub-field SUB_FIELD_1 is reset and the second sub-field SUB_FIELD_2 is set in order for the ready-busy field RB_FIELD to set the ready-busy state RB_STATE of the memory device 110.

Accordingly, if the response message RESP_MSG received from the memory device 110 indicates the ready-busy state RB_STATE in which the value of the ready-busy field RB_FIELD does not exist, the memory controller 120 may determine that the ready-busy field RB_FIELD indicates whether or not the target command TGT_CMD is inexecutable, instead of indicating the ready-busy state RB_STATE of the memory device 110.

As described above, in the case where the ready-busy field RB_FIELD indicates whether or not the target command TGT_CMD is inexecutable in the response message RESP_MSG, the memory controller 120 is required to identify the ready-busy state RB_STATE of the memory device 110 through a separate status-read command.

In some implementations, the memory controller 120 and the memory device 110 identify the ready-busy state RB_STATE of the memory device 110 through a subsequent status-read command. The subsequent status-read command denotes the status-read command, which is generated after the response message RESP_MSG, indicating whether or not the target command TGT_CMD is inexecutable, is generated.

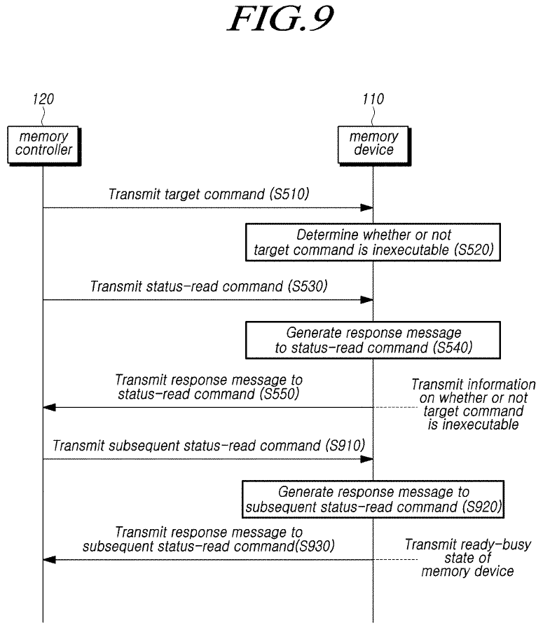

FIG. 9 is a flowchart illustrating an example of an operation in which a memory controller 120 and a memory device 110 process a subsequent status-read command based on embodiments of the disclosed technology.

As illustrated in FIG. 5, the memory controller 120 may transmit a target command TGT_CMD to the memory device 110 (S510). In addition, the memory device 110 determines whether or not the target command TGT_CMD received from the memory controller 120 is inexecutable (S520). Thereafter, the memory controller 120 may transmit a status-read command to the memory device 110 (S530). The memory device 110 may generate a response message RESP_MSG to the status-read command (S540). In addition, the memory device 110 may transmit the generated response message RESP_MSG to the memory controller 120 (S550).

Thereafter, the memory controller 120 may transmit a subsequent status-read command to the memory device 110 (S910).

The memory device 110 may receive the subsequent status-read command, and may generate a response message to the subsequent status-read command (S920). In this case, the memory device 110 may configure a value indicating the ready-busy state RB_STATE of the memory device 110 in the field RB_FIELD, indicating the ready-busy state RB_STATE of the memory device 110, in the response message to the subsequent status-read command.

In addition, the memory device 110 may transmit, to the memory controller 120, the response message to the subsequent status-read command (S930). The memory controller 120 may identify the ready-busy state RB_STATE of the memory device 110 through the response message to the subsequent status-read command.

That is, the memory device 110 may respond to the memory controller 120 regarding the ready-busy state of the memory device 110 through the response message to the subsequent status-read command received from the memory controller 120. Meanwhile, the operation described above may be performed by the response circuit 113 of the memory device 110.

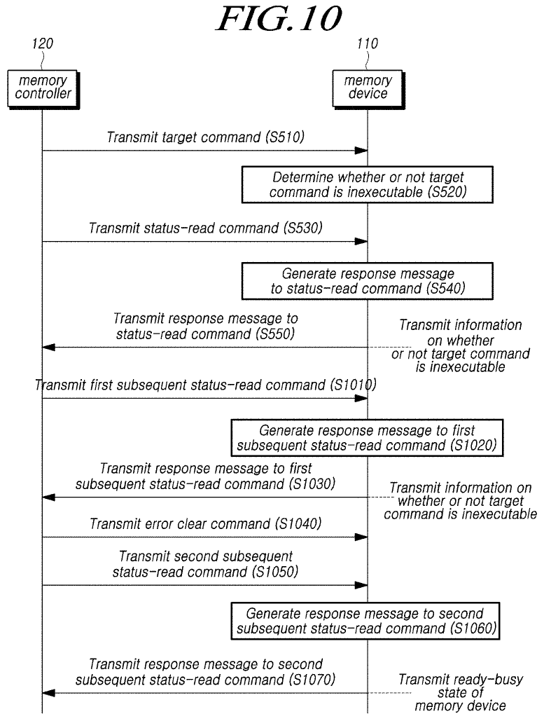

FIG. 10 is a flowchart illustrating another example of an operation in which a memory controller 120 and a memory device 110 process a subsequent status-read command based on embodiments of the disclosed technology.

As illustrated in FIG. 5, the memory controller 120 may transmit a target command TGT_CMD to the memory device 110 (S510). In addition, the memory device 110 determines whether or not the target command TGT_CMD received from the memory controller 120 is inexecutable (S520). Thereafter, the memory controller 120 may transmit a status-read command to the memory device 110 (S530). The memory device 110 may generate a response message RESP_MSG to the status-read command (S540). In addition, the memory device 110 may transmit the generated response message RESP_MSG to the memory controller 120 (S550).

The memory controller 120 may transmit a separate error clear command to the memory device 110 in order to identify the ready-busy state of the memory device 110.

The error clear command is a command making a request to the memory device 110 for responding to the memory controller 120 with a ready-busy state RB_STATE of the memory device 110 through a response message to the status-read command. That is, after receiving the error clear command from the memory controller 120, the memory device 110 may respond to the memory controller 120 with a ready-busy state RB_STATE of the memory device 110 through a response message to a subsequent status-read command received from the memory controller 120.

In some implementations, the memory controller 120 may transmit a first subsequent status-read command to the memory device 110 (S1010). In addition, the memory device 110 may generate a response message to the first subsequent status-read command (S1020). In this case, the memory device 110 configures information indicating whether or not the target command TGT_CMD is inexecutable in the ready-busy field RB_FIELD in the response message to the first subsequent status-read command. This is due to the fact that the memory device 110 has not yet received the error clear command from the memory controller 120.

In addition, the memory device 110 may transmit the response message to the first subsequent status-read command to the memory controller 120 (S1030).

The memory controller 120 may transmit an error clear command to the memory device 110 (S1040). After receiving the error clear command, the memory device 110 may configure a value indicating the ready-busy state RB_STATE of the memory device 110 in the ready-busy field RB_FIELD in the response message to the status-read command.

The memory controller 120 may transmit a second subsequent status-read command to the memory device 110 (S1050). In addition, the memory device 110 may generate a response message to the second subsequent status-read command (S1060). In this case, the memory device 110 configures a value indicating the ready-busy state RB_STATE of the memory device 110 in a field RB_FIELD indicating the ready-busy state RB_STATE of the memory device 110 in the response message to the second subsequent status-read command.

In addition, the memory device 110 may transmit the response message to the second subsequent status-read command to the memory controller 120 (S1070). Meanwhile, the operation described above may be performed by the response circuit 113 of the memory device 110.

As shown in FIGS. 7 to 10, the memory device 110 may indicate whether or not the target command TGT_CMD is inexecutable through the ready-busy field RB_FIELD in the response message RESP_MSG.

However, the memory device 110 may indicate whether or not the target command TGT_CMD is inexecutable through a field other than the ready-busy field RB_FIELD in the response message RESP_MSG.

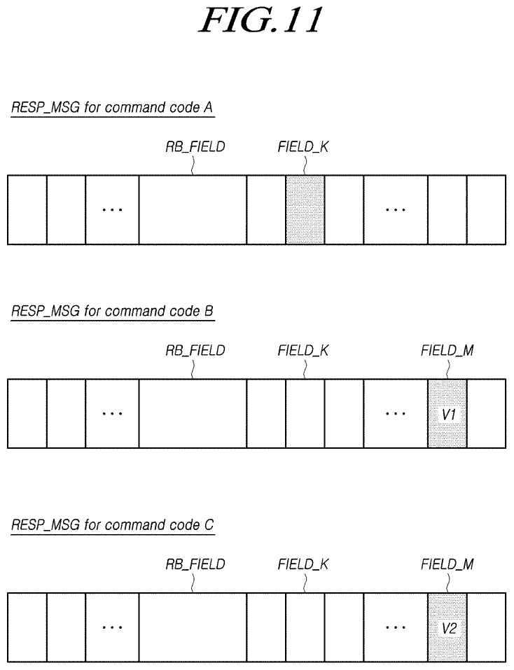

FIG. 11 is a diagram illustrating another example of a format of a response message RESP_MSG to a status-read command based on embodiments of the disclosed technology.

The response circuit 113 of the memory device 110 may differently configure i) a field indicating whether or not the target command TGT_CMD is inexecutable or ii) a value indicating whether or not the target command TGT_CMD is inexecutable in a response message to a corresponding status-read command depending on a command code of the status-read command.

The command code of the status-read command is a value for distinguishing between status-read commands in different formats. For example, the command code of the status-read command may be an 8-bit hexa-code (e.g., 70h/78h/7Ah/7Bh).

Referring to FIG. 11, when the command code of the status-read command is “A” (e.g., 70h), the memory device 110 may indicate whether or not the target command TGT_CMD is inexecutable using a field “K” FIELD_K among the fields of the response message RESP_MSG to the status-read command.

In addition, when the code of the status-read command is “B” (e.g., 78h), the memory device 110 may indicate whether or not the target command TGT_CMD is inexecutable using a field “M” FIELD_M, which is different from the field “K” FIELD_K, among the fields of the response message RESP_MSG to the status-read command.

Meanwhile, even if the code of the status-read command is “C” (e.g., 7Bh), the memory device 110 may indicate whether or not the target command TGT_CMD is inexecutable through a field “M” FIELD_M among the fields of the response message RESP_MSG to the status-read command.

The memory device 110 may differently configure the value of the field “M” FIELD_M, which is used to indicate whether or not the target command TGT_CMD is inexecutable depending on the code of the status-read command.

For example, if the code of the status-read command is “B”, the memory device 110 may configure the value of the field “M” FIELD_M to be a first value V1 in order to indicate that the target command TGT_CMD is inexecutable. On the other hand, if the code of the status-read command is “C”, the memory device 110 may configure the value of the field “M” FIELD_M to be a second value V2, which is different from the first value V1, in order to indicate that the target command TGT_CMD is inexecutable. For example, if the first value V1 is 0, the second value V2 may be 1, and if the first value V1 is 1, the second value V2 may be 0.

As discussed above, the memory device 110 may transmit, to the memory controller 120, an indication as to whether or not the target command TGT_CMD is inexecutable through a response message to a status-read command has been described.

As will be discussed below, the memory device 110 may transmit information on the target command TGT_CMD to the memory controller 120.

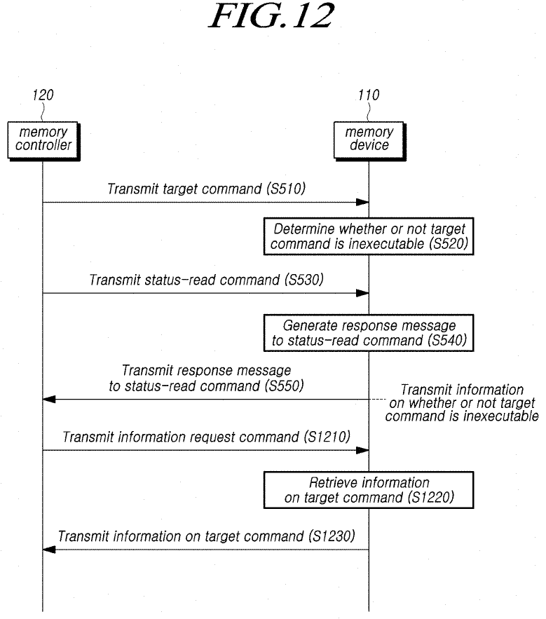

FIG. 12 is a flowchart illustrating an operation in which a memory controller 120 and a memory device 110 process an information request of a target command based on embodiments of the disclosed technology.

As illustrated in FIG. 5, the memory controller 120 may transmit a target command TGT_CMD to the memory device 110 (S510). In addition, the memory device 110 determines whether or not the target command TGT CMD received from the memory controller 120 is inexecutable (S520). Thereafter, the memory controller 120 may transmit a status-read command to the memory device 110 (S530). The memory device 110 may generate a response message RESP_MSG to the status-read command (S540). In addition, the memory device 110 may transmit the generated response message RESP_MSG to the memory controller 120 (S550).

The memory controller 120 may transmit, to the memory device 110, a separate information request command, instead of a status-read command, in order to make a request to the memory device 110 for information on the target command TGT_CMD (S1210).

After receiving the information request command from the memory controller 120, the memory device 110 may retrieve information on the target command TGT_CMD (S1220). In this case, the memory device 110 may retrieve information on the target command TGT_CMD from any one of the memory blocks BLK in the memory device 110 or from a volatile memory (not shown) included in the memory device 110 as described in FIG. 4 above.

In addition, the memory device 110 may transmit information on the target command TGT_CMD to the memory controller 120 (S1230). Meanwhile, the operation described above may be performed by the response circuit 113 of the memory device 110.

When the memory device 110 receives the information request command requesting information on the target command TGT_CMD from the memory controller 120, the memory device 110 may determine the information to be transmitted to the memory controller 120 among the information on the target command TGT_CMD.

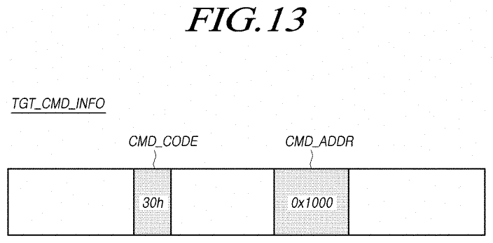

FIG. 13 is a diagram illustrating an example of the format of an information message TGT_CMD_INFO of a target command TGT_CMD based on embodiments of the disclosed technology.

Referring to FIG. 13, the information message TGT_CMD_INFO on the target command TGT_CMD used to transmit information on the target command TGT_CMD to the memory controller 120 may include i) a command code CMD_CODE of the target command TGT_CMD and ii) address information CMD_ADDR corresponding to the target command TGT_CMD.

The command code CMD_CODE of the target command TGT_CMD is a value representing the operation indicated by the target command TGT_CMD. Like the status-read command, the command code CMD_CODE of the target command TGT_CMD may be an 8-bit hexa-code (e.g., 30h/FFh/60h).

For example, if the target command TGT_CMD is a page read command (corresponding to a command code 30h), the value of the command code CMD_CODE of the target command TGT_CMD in the information message TGT_CMD_INFO of the target command TGT_CMD may be 30h.

The address information CMD_ADDR corresponding to the target command TGT_CMD is a value representing the address of the memory device 110 indicated by the target command TGT_CMD on which the operation is to be executed.

For example, if the target command TGT_CMD is a page read command for reading a page with an address 0×1000, the value of the address information CMD_ADDR corresponding to the target command TGT_CMD may be 0×1000 in the information message TGT_CMD_INFO of the target command.

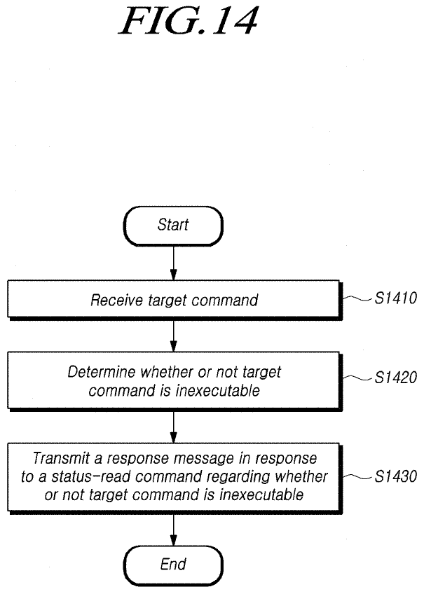

FIG. 14 is a flowchart illustrating an operation method of a memory device 110 based on embodiments of the disclosed technology.

The operation method of the memory device 110 may include a step of receiving a target command TGT_CMD from the memory controller 120 (S1410).

In addition, the operation method of the memory device 110 may include a step of determining whether or not the target command TGT_CMD is inexecutable (S1420).

In step S1420, the memory device 110 may determine whether or not the target command is inexecutable depending on the ready-busy state RB_STATE of the memory device 110. The ready-busy state RB_STATE of the memory device 110 may be determined to be i) a ready state RDY, ii) a first busy state BUSY_1, or iii) a second busy state BUSY_2, based on the internal busy-state value INT_BUSY and the external busy-state value EXT_BUSY, determined depending on the operation performed by the memory device 110.

In addition, the operation method of the memory device 110 may include a step of transmitting, to the memory controller 120, information on whether or not the target command TGT_CMD is inexecutable through the response message RESP_MSG to the status-read command received from the memory controller 120 (S1430).

For example, the memory device 110 may respond to the memory controller 120 regarding whether or not the target command TGT_CMD is inexecutable through the ready-busy field RB_FIELD indicating the ready-busy state RB_STATE of the memory device 110, among the fields of the response message RESP_MSG. If the target command TGT_CMD is inexecutable, i) a first sub-field SUB_FIELD_1 indicating the internal busy-state value INT_BUSY of the memory device 110 may be reset, and ii) a second sub-field SUB_FIELD_2 indicating the external busy-state value EXT_BUSY of the memory device 110 may be set, among the sub-fields included in the ready-busy field RB_FIELD.

As another example, the memory device 110 may configure i) a field indicating whether or not the target command TGT_CMD is inexecutable or ii) a value indicating whether or not the target command TGT_CMD is inexecutable, among the fields in the response message RESP_MSG, to be different depending on a command code of the status-read command.

In addition to steps S1410, S1420, and S1430 described above, the operation method of the memory device 110 may further include, for example, a step of responding to the memory controller 120 with the ready-busy state RB_STATE of the memory device 110 through a response message to a subsequent status-read command received from the memory controller 120 after transmitting the response message RESP_MSG to the memory controller 120.

In addition to steps S1410, S1420, and S1430 described above, the operation method of the memory device 110 may further include, as another example, a step of responding to the memory controller with the ready-busy state RB_STATE of the memory device 110 through a response message to a subsequent status-read command received from the memory controller 120 after receiving an error clear command from the memory controller 120. The error clear command is a command making a request to the memory device 110 for indicating the ready-busy state RB_STATE of the memory device 110 to the memory controller 120 through a response message to the status-read command.

In addition to steps S1410, S1420, and S1430 described above, the operation method of the memory device 110 may further include a step of transmitting information on the target command TGT_CMD to the memory controller 120 when an information request command requesting information on the target command TGT_CMD is received from the memory controller 120. In this case, the information on the target command TGT_CMD may include a command code CMD_CODE of the target command TGT_CMD and address information CMD_ADDR corresponding to the target command TGT_CMD.

In some implementations, the operation of the memory controller 120 described above may be controlled by the control circuit 123, and may be performed in such a manner that the processor 124 executes (drives) firmware in which the overall operation of the memory controller 120 is programmed.

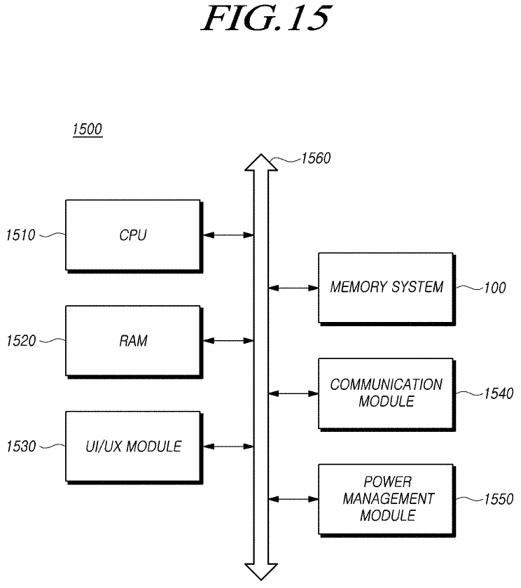

FIG. 15 is a diagram illustrating the configuration of a computing system 1500 based on an embodiment of the disclosed technology.

Referring to FIG. 15, the computing system 1500 based on an embodiment of the disclosed technology may include: a memory system 100 electrically connected to a system bus 1560; a CPU 1510 configured to control the overall operation of the computing system 1500; a RAM 1520 configured to store data and information related to operations of the computing system 1500; a user interface/user experience (UI/UX) module 1530 configured to provide the user with a user environment; a communication module 1540 configured to communicate with an external device as a wired and/or wireless type; and a power management module 1550 configured to manage power used by the computing system 1500.

The computing system 1500 may be a personal computer (PC) or may include a mobile terminal such as a smartphone, a tablet or various electronic devices.

The computing system 1500 may further include a battery for supplying an operating voltage, and may further include an application chipset, a graphic-related module, a camera image processor, and a DRAM. Other elements would be obvious to a person skilled in the art.

The memory system 100 may include not only a device configured to store data in a magnetic disk such as a hard disk drive (HDD), but also a device configured to store data in a nonvolatile memory such as a solid state drive (SSD), a universal flash storage device, or an embedded MMC (eMMC) device. The non-volatile memory may include a read only memory (ROM), a programmable

ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), and the like. In addition, the memory system 100 may be implemented as storage devices of various types and mounted inside various electronic devices.

Based on embodiments of the disclosed technology described above, the operation delay time of the memory system may be reduced or minimized. In addition, the disclosed technology can be implemented in a way that reduces or minimizes an overhead occurring in the process of calling a specific function. Although various embodiments of the disclosed technology have been described for illustrative purposes, those skilled in the art will appreciate that various modifications, additions and substitutions are possible based on what is described and illustrated in this patent document.

What is claimed is:

1. A memory device comprising:
a reception circuit configured to receive a target command from a memory controller that is outside the memory device and is operable to control the memory device, wherein the target command is a command that is intended for a memory device to execute;
a determination circuit in communication with the reception circuit and configured to determine whether or not the target command is inexecutable by the memory device; and
a response circuit in communication with the determination circuit to receive information from the determination circuit on whether or not the target command is inexecutable and configured to transmit a response message in response to a status-read command received from the memory controller to inform the memory controller regarding whether or not the target command is inexecutable.

2. The memory device of claim 1, wherein the determination circuit is configured to use a ready-busy state of the memory device to determine whether or not the target command is inexecutable, and
wherein the ready-busy state of the memory device is determined to be a ready state, a first busy state, or a second busy state, based on an internal busy-state value and an external busy-state value determined based on an operation performed by the memory device.

3. The memory device of claim 2, wherein the response message includes a ready-busy field indicating the ready-busy state of the memory device and indicates whether or not the target command is inexecutable through the ready-busy field.

4. The memory device of claim 3, wherein, upon determination that the target command is inexecutable, the response circuit is configured to:
reset a first sub-field of the ready-busy field indicating the internal busy-state value of the memory device; and
set a second sub-field of the ready-busy field indicating the external busy-state value of the memory device.

5. The memory device of claim 3, wherein the response circuit is configured to transmit another response message in response to a subsequent status-read command received from the memory controller.

6. The memory device of claim 3, wherein the response circuit is configured to, upon receipt of an error clear command from the memory controller, transmit another response message in response to a subsequent status-read command received from the memory controller, and
wherein the error clear command is configured to make a request to the memory device for responding to the memory controller with the ready-busy state of the memory device through a response message to a status-read command.

7. The memory device of claim 2, wherein the response message includes a field or a value indicating whether or not the target command is inexecutable, and wherein the field or the value are set differently depending on a command code of the status-read command.

8. The memory device of claim 1, wherein the response circuit is configured to transmit information on the target command to the memory controller in response to an information request command requesting information on the target command from the memory controller.

9. The memory device of claim 8, wherein the information on the target command comprises a command code of the target command and address information corresponding to the target command.

10. An operation method of a memory device, the method comprising:
receiving a target command from a memory controller;
determining whether or not the target command is inexecutable; and
transmitting a response message in response to a status-read command received from the memory controller to inform the memory controller regarding whether or not the target command is inexecutable.

11. The method of claim 10, wherein the determining whether or not the target command is inexecutable is based on a ready-busy state of the memory device, and
wherein the ready-busy state of the memory device is determined to be a ready state, a first busy state, or a second busy state, based on an internal busy-state value and an external busy-state value determined based on an operation performed by the memory device.

12. The method of claim 11, wherein the response message includes a ready-busy field indicating the ready-busy state of the memory device and indicates whether or not the target command is inexecutable through the ready-busy field.

13. The method of claim 12, further comprising, upon determination that the target command is inexecutable, resetting a first sub-field of the ready-busy field indicating the internal busy-state value of the memory device, and setting a second sub-field of the ready-busy field indicating the external busy-state value of the memory device.

14. The method of claim 12, further comprising transmitting another response message in response to a subsequent status-read command received from the memory controller.

15. The method of claim 12, further comprising, upon receipt of an error clear command from the memory controller, transmitting another response message in response to a subsequent status-read command received from the memory controller,
wherein the error clear command is configured to make a request to the memory device for indicating the ready-busy state of the memory device to the memory controller through a response message to a status-read command.

16. The method of claim 11, wherein the response message includes a field or a value indicating whether or not the target command is inexecutable, and wherein the field or the value are set differently depending on a command code of the status-read command.

17. The method of claim 10, further comprising transmitting information on the target command to the memory controller in response to an information request command requesting information on the target command.

18. The method of claim 17, wherein the information on the target command comprises a command code of the target command and address information corresponding to the target command.

19. A memory system comprising:
a memory device including memory cells for storing data; and
a memory controller configured to provide a target command to control the memory device,
wherein the memory device is configured to:
receive the target command from the memory controller;
determine whether or not the target command is inexecutable; and
transmit a response message in response to a status-read command received from the memory controller to inform the memory controller regarding whether or not the target command is inexecutable.

20. The memory system of claim 19, wherein whether or not the target command is inexecutable is determined using a ready-busy state of the memory device.
